(19) United States
(12) Patent Application Publication
(10) Pub. No.: US 2008/0278907 A1
(43) Pub. Date: Nov. 13, 2008

(54) FASTENING APPARATUS

(76) Inventor: Ying-Hui Shih, Taipei (TW)

Correspondence Address: NORTH AMERICA INTELLECTUAL PROPERTY CORPORATION, P.O. BOX 506, MERRIFIELD, VA, 22116, US

(21) Appl. No.: 12/040,926

(22) Filed: Mar. 3, 2008

Related U.S. Application Data
(60) Provisional application No. 60/917,068, filed on May 10, 2007.

(51) Int. Cl. G06F 1/16; A44B 21/00; H05K 5/00; F16D 3/52

(52) U.S. Cl. 361/686; 24/545; 403/91; 361/759

(57) ABSTRACT

A fastening apparatus for fastening at least an interface card includes a fixed support frame and at least a movable fastening structure. Additionally, the fastening structure can be utilized to perform a fastening or un-fastening operation with high speed on a plurality of interface cards simultaneously in the computer chassis without using any screws. Thus, the disclosed fastening apparatus can reduce cost of assembly and repair of the computer, and also can reduce time for assembly and repair of the computer.

### CROSS REFERENCE TO RELATED APPLICATIONS

This application claims the benefit of U.S. Provisional Application No. 60/917,068, filed on May 10, 2007 and included herein by reference.

### BACKGROUND OF THE INVENTION

1. Field of the Invention

The present invention relates to a fastening apparatus, and more particularly, to a fastening apparatus for fastening at least an interface card in a chassis without using any screws.

2. Description of the Prior Art

Along with recent improvements of semiconductor manufacturing technologies, computers have become an essential part of everyday life. One important area in computer applications for manufacturers and end users is fastening techniques for interface cards (such as a peripheral component interconnect (PCI) interface card) utilized in computer equipment such as personal computers or servers.

In the prior art, the fastening apparatus for the interface card is a plurality of screws to screw the interface card on a support frame to fasten the interface card in a computer chassis. Since the interface card in the computer is usually a replaceable element, however, users often frequently fasten or un-fasten the interface card according to using requirements. Thus, using the screws to fasten the interface card causes inconvenience for the user when assembling the computer. For example, the user may need some specific tools for assembly, and the screws will be easily lost when they are removed from the computer chassis. Besides, using the screws to fasten the interface card does not satisfy the requirements of high speed and low labor cost in the production line, and the prior art can only fasten one interface card at one time. Thus, a fastening apparatus for performing a fastening or un-fastening operation on a plurality of interface cards simultaneously with high speed in a chassis without using any screw is required.

### SUMMARY OF THE INVENTION

It is therefore one of the objectives of the present invention to provide a fastening apparatus for fastening at least an interface card in a chassis without using any screw, to solve the above problems.

According to an embodiment of the present invention, a fastening apparatus for fastening at least an interface card is disclosed. The fastening apparatus includes a fixed support frame and a movable fastening structure. The fixed support frame includes: a first fastening structure, disposed in a side of the fixed support frame; and a second fastening structure, having at least a first plate contacting area, for contacting a first part of a plate of the interface card. The movable fastening structure includes: a main structure, having a first end section and a main body section; and a rotary axis, fixedly connected to the main structure and disposed on the first end section, wedged in the first fastening structure in a rotatable way, wherein the first part of the plate is clamped between the main body section and the first plate contacting area when the main structure rotates to a predetermined position via the rotating axis.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a three-dimensional view of a fastening apparatus for fastening a plurality of interface cards in a computer chassis according to an embodiment of the present invention.

FIG. 2 shows a three-dimensional view of the fastening apparatus in FIG. 1 before assembly.

FIG. 3 shows a three-dimensional view of the fastening apparatus in FIG. 2 after assembly.

FIG. 4 shows a simplified side view of the interface card and the fastening apparatus.

### DETAILED DESCRIPTION

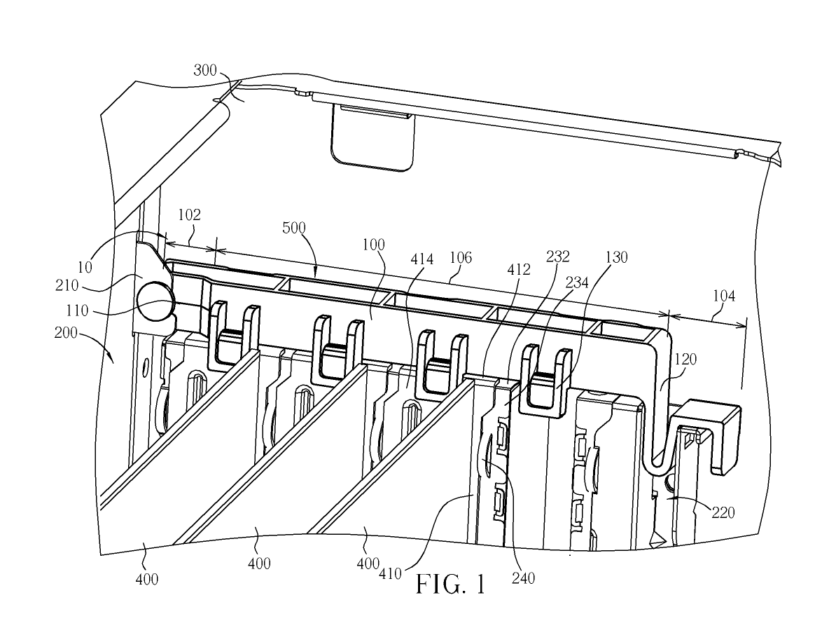

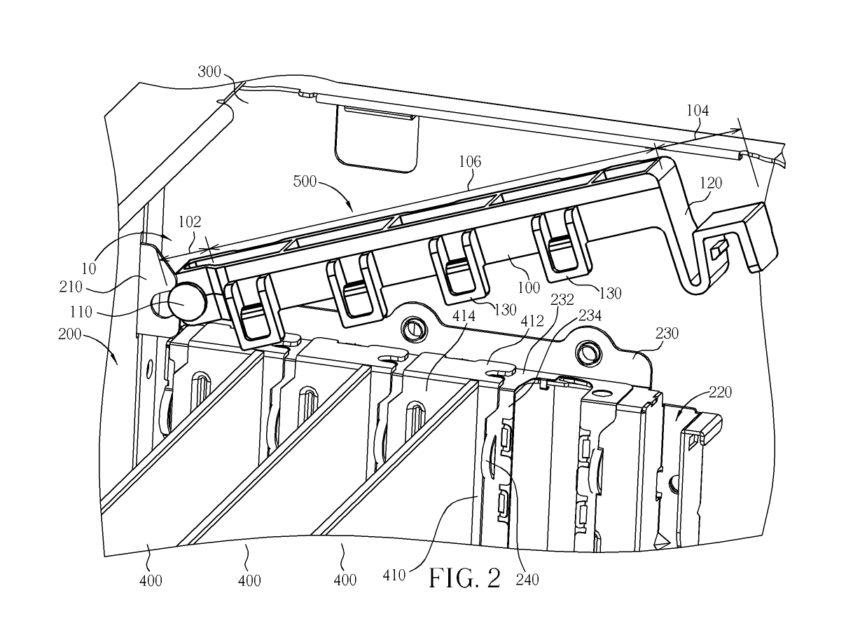

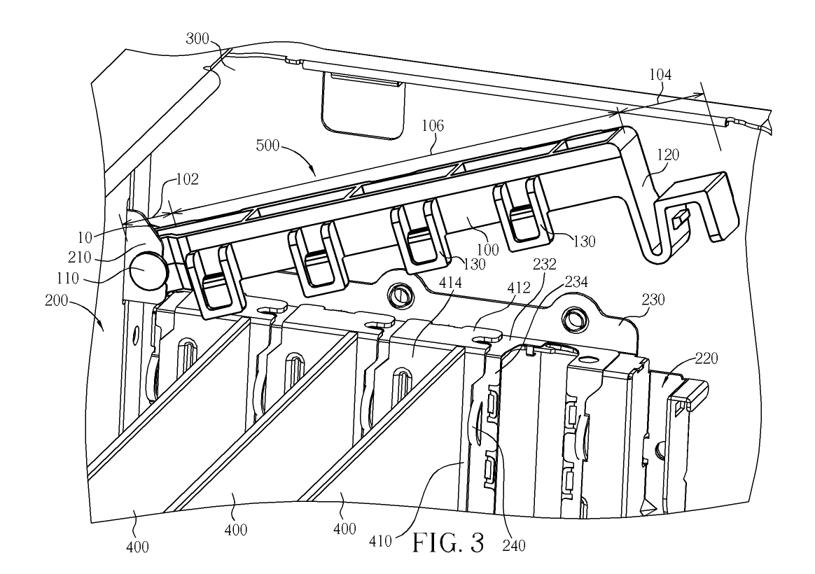

Please refer to FIG. 1, FIG. 2, and FIG. 3 together. FIG. 1 shows a three-dimensional view of a fastening apparatus 10 for fastening a plurality of interface cards 400 (such as three PCI interface cards) in a computer chassis 300 according to an embodiment of the present invention. FIG. 2 shows a three-dimensional view of the fastening apparatus 10 in FIG. 1 before assembly. FIG. 3 shows a three-dimensional view of the fastening apparatus 10 in FIG. 2 after assembly.

As shown in FIG. 1, FIG. 2, and FIG. 3, the fastening apparatus 10 includes a fixed support frame 200 and a movable fastening structure 500. The fixed support frame includes: a first fastening structure 210 disposed in one side of the fixed support frame 200; a second fastening structure 230 having a first plate contacting area 232 and a second plate contacting area 234 for contacting a first part 412 and a second part 414 respectively of a plate 410 of the interface card 400; a third fastening structure 220, wherein the second fastening structure 230 is disposed between the first fastening structure 210 and the third fastening structure 220; and a plurality of protruding parts 240 fixedly connected to the second fastening structure 230 and disposed on one side of the second plate contacting area 234.

The movable fastening structure 500 includes: a main structure 100 having a first end section 102, a second end section 104, and a main body section 106, wherein the main body section 106 is disposed between the first end section 102 and the second end section 104; a rotary axis 110 fixedly connected to the main structure 100 and disposed on the first end section 102, and wedged in the first fastening structure 210 in a rotatable way; an elastic body 120 fixedly connected to the main structure 100 and disposed on the second end section 104; and a plurality of protruding objects 130 fixedly connected to the main structure 100 and disposed on the main body section 106, and protruding at one side of the main body section 106 facing the second fastening structure 230. When the main structure 100 rotates to a predetermined position via the rotating axis 110, the elastic body 120 is wedged in the third fastening structure 220 in an elastic way, and the first part 412 of the plate 410 is clamped between the main body section 106 and the first plate contacting area 232, and the second part 414 of the plate 410 is clamped between the protruding objects 130 and the second plate contacting area 234, and the interface card 400 is clamped between the protruding objects 130 and the protruding parts 240. In this way, all the interface cards 400 can be fastened in the computer chassis 300.

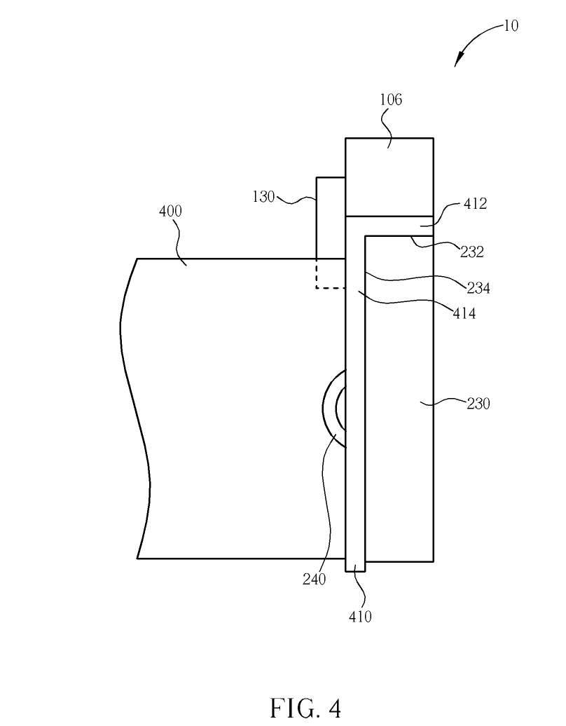

Please refer to FIG. 4. FIG. 4 shows a simplified side view of the interface card 400 and the fastening apparatus 10. As shown in FIG. 4, when using the fastening apparatus 10 to fasten the interface card 400, the first part 412 of the plate 410 is clamped between the main body section 106 and the first plate contacting area 232 of the second fastening structure 230, and the second part 414 of the plate 410 is clamped between the protruding objects 130 and the second plate contacting area 234 of the second fastening structure 230, and the interface card 400 is clamped between the protruding objects 130 and the protruding parts 240. Thus, the interface card 400 can be fully fastened.

Please note that the above embodiment is only for illustrative purposes and is not meant as a limitation of the present invention. For example, the number of the protruding objects 130 is not limited to four, and can increase or decrease according to design requirements of different computer chassis.

In addition, the fastening apparatus 10 can be integrated in the computer chassis 300. The material of the fixed support frame 200 can include various metals, and material of the movable fastening structure 500 can include plastics and/or various metals. The main structure 100, the rotating axis 110, the elastic body 120, and the protruding objects 130 can be formed from a single mold. Please note that the above embodiment is only for illustration purposes and is not meant as a limitation of the present invention.

Briefly summarized, the disclosed fastening apparatus can be utilized to perform a fastening or un-fastening operation with high speed on a plurality of interface cards simultaneously in the computer chassis without using any screws. Thus, the disclosed fastening apparatus can reduce cost of assembly and repair of the computer, and also can reduce time for assembly and repair of the computer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fastening apparatus for fastening at least an interface card, comprising:
a fixed support frame, comprising:
a first fastening structure, disposed in a side of the fixed support frame; and
a second fastening structure, having at least a first plate contacting area, for contacting a first part of a plate of the interface card; and
a movable fastening structure, comprising:
a main structure, having a first end section and a main body section; and
a rotary axis, fixedly connected to the main structure, disposed on the first end section and wedged in the first fastening structure in a rotatable way, wherein the first part of the plate is clamped between the main body section and the first plate contacting area when the main structure rotates to a predetermined position via the rotating axis.

2. The fastening apparatus of claim 1, wherein the fixed support frame further comprises a third fastening structure, and the second fastening structure is disposed between the first fastening structure and the third fastening structure; the main structure further comprises a second end section, and the main body section is disposed between the first end section and the second end section; and the movable fastening structure further comprises an elastic body fixedly connected to the main structure and disposed on the second end section, and the elastic body is wedged in the third fastening structure in an elastic way when the main structure rotates to the predetermined position via the rotating axis.

3. The fastening apparatus of claim 1, wherein the second fastening structure further comprises at least a second plate contacting area, for contacting a second part of the plate of the interface card, and the movable fastening structure further comprises:
at least a protruding object, fixedly connected to the main structure, disposed on the main body section, and protruding at a side of the main body section facing the second fastening structure, wherein the second part of the plate is clamped between the protruding object and the second plate contacting area when the main structure rotates to the predetermined position via the rotating axis.

4. The fastening apparatus of claim 3, wherein the fixed support frame further comprises:
at least a protruding part, fixedly connected to the second fastening structure and disposed on a side of the second plate contacting area, wherein the interface card is further clamped between the protruding object and the protruding part when the main structure rotates to the predetermined position via the rotating axis.

5. The fastening apparatus of claim 3, wherein the fixed support frame further comprises a third fastening structure, and the second fastening structure is disposed between the first fastening structure and the third fastening structure; the main structure further comprises a second end section, and the main body section is disposed between the first end section and the second end section; the movable fastening structure further comprises an elastic body fixedly connected to the main structure and disposed on the second end section, and the elastic body is wedged in the third fastening structure in an elastic way when the main structure rotates to the predetermined position via the rotating axis; and the main structure, the rotating axis, the elastic body, and the protruding object are formed from a single mold.

6. The fastening apparatus of claim 1, being integrated in a computer chassis.

7. The fastening apparatus of claim 6, wherein the interface card is a peripheral component interconnect (PCI) interface card.

8. The fastening apparatus of claim 1, wherein material of the fixed support frame comprises metal.

9. The fastening apparatus of claim 1, wherein material of the movable fastening structure is selected from a group consisting of plastics and metal.
